(19) United States
(12) Patent Application Publication
(10) Pub. No.: US 2009/0224263 A1
(43) Pub. Date: Sep. 10, 2009

(54) Generating Stress in a Field Effect Transistor

(75) Inventor: Katsura Miyashita, Kanagawa (JP)

Correspondence Address: BANNER & WITCOFF, LTD., 1100 13th STREET, N.W., SUITE 1200, WASHINGTON, DC, 20005-4051, US

(73) Assignee: TOSHIBA AMERICA ELECTRONIC COMPONENTS, INC., Irvine, CA (US)

(21) Appl. No.: 12/043,139

(22) Filed: Mar. 6, 2008

(51) Int. Cl. H01L 29/15

(52) U.S. Cl. 257/77; 257/E29.072

(57) ABSTRACT

A structure for generating stress in a field effect transistor is described. Combinations of materials are described that when juxtaposed provide one of tensile or compressive stress to a channel region. In one or more aspects, tensile stress is provided to a channel region by materials having similar but different lattice constants.

### TECHNICAL FIELD

Aspects of the following disclosure relate generally to the intentional generation of tensile (or compressive) stress in field effect transistors by using different materials outside the channel region than those used in channel regions.

### BACKGROUND

Process induced stress has been used in advanced complimentary metal oxide substrate (CMOS) large scale integrated circuit (LSI) products. Process-induced stress can improve electron and/or hole mobility in field effect transistor (FET) channels. For n-type FETs (NFETs), applying uni-axial tensile stress to the channel region by a tensile stress contact liner is known. Similarly, for p-type FETs (PFETs), applying uni-axial compressive stress to a channel region by a compressive stress contact liner is also known.

Some physical structures can affect how effective a stress-inducing contact liner may be. For instance, a tungsten contact plug in proximity to a FET can weaken the uni-axial stress effect generated by using a stress contact liner, due to the penetration of the stress-inducing layer by the tungsten contact plug.

Referring to FIG. 1, a semiconductor structure 100 is shown with a SiN stress liner 101 as an outer stressing layer over two adjacent p-type FETs (PFET's) 102, 103. Source/drain regions 102a are located on the sides of the channel region 102b of PFET 102. Similarly, source/drain regions 103a are located on the sides of channel region 103b of PFET 103.

Compressive stress caused by the stress liner 101 is felt at the channel regions 102b and 103b. The direction of the stress is shown by arrows 104-107. FIG. 1 also shows tungsten contact plugs 108, 109, which are used to contact the source/drain regions 102a.

Although compressive stress is desired for the PFETs of FIG. 1 so as to adjust the charge carrier mobility, the resultant compressive stress is not equivalent for the PFETs 102 and 103. The compressive stress is reduced because of the tungsten contact plugs 108, 109 that interrupt the continuity of the SiN stress liner 101 near the PFETs 102 and 103. For PFET 102, the tungsten contact plugs 108, 109 affect both sides of the PFET 102 approximately equally because of the tungsten contact plugs' 108, 109 proximity to the channel region 102b. This generally equal compressive stress is shown by the generally equal arrows 104 and 105.

Similarly, the compressive stress felt at channel 103b is also reduced based on the proximity of tungsten plug 109 to the channel region 103b. However, unlike the generally equal stress from both sides of the channel 102b, the compressive stress at channel 103b is greater than the compressive stress felt at channel 102b due to no contact plug near the right side of the channel 103b. However, the degree of compressive stress is unequal across the channel due to the proximity of tungsten plug 109 to the channel 103b but no tungsten plug on the other side of the channel.

The closer a tungsten plug is to a field effect transistor, the less effectiveness a stress liner has to influence the stress of a channel region (for PFETs and NFETs). Therefore, process induced stress caused by using a stress contact liner is dependent upon contact position in the layout of the integrated circuit. Since gate-to-contact plug distance is expected to be narrower in each generation of an integrated circuit, stress liners may likely be less effective to provide stress for channel regions of FETs. In short, the use of stress liners may not be readily scalable as process dimensions shrink.

### SUMMARY

One or more aspects of the invention relate to providing stress to channel regions of field effect transistors using various materials as part of the channel and different materials outside of the channel.

Various illustrative structures are described, along with various techniques involved in manufacturing these structures.

### BRIEF DESCRIPTION OF THE DRAWINGS

FIG. 1 is a side cross-sectional view showing a stress liner with contact plugs.

FIG. 2 is a side cross-sectional view showing a structure of field effect transistor as used in one or more embodiments of the present invention.

FIG. 3 shows effective strain between Carbon and Germanium in accordance with one or more aspects of the present invention.

FIG. 4 shows a first embodiment of the present invention.

FIG. 5 shows a second embodiment of the present invention.

FIG. 6 shows a third embodiment of the present invention.

FIG. 7 shows a fourth embodiment of the present invention.

FIG. 8 shows a fifth embodiment of the present invention.

FIG. 9 shows a sixth embodiment of the present invention.

FIG. 10 shows a seventh embodiment of the present invention.

### DETAILED DESCRIPTION

Aspects of the present invention relate to providing stress to a channel region for field effect transistors using various materials in the crystalline structure of the semiconductor.

It is noted that various connections are set forth between elements in the following description. It is noted that these connections in general and, unless specified otherwise, may be direct or indirect and that this specification is not intended to be limiting in this respect.

General Structure of a Field Effect Transistor

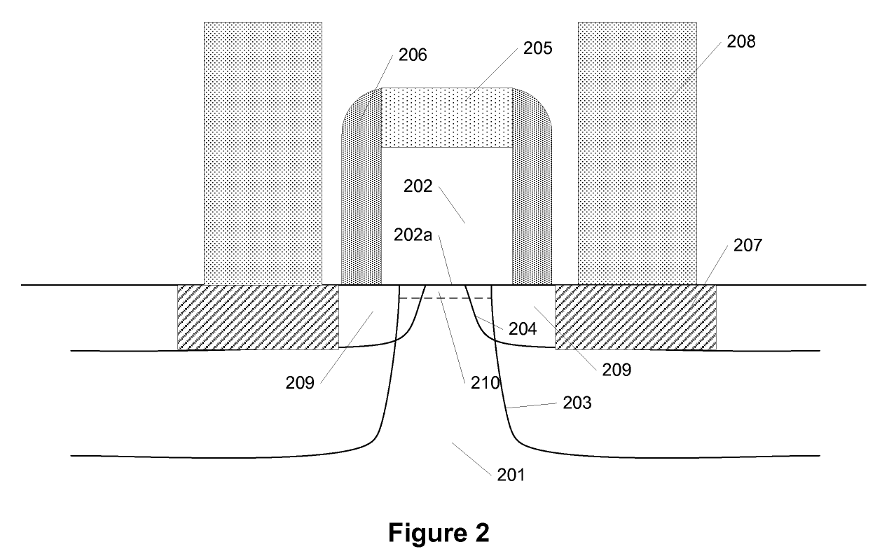

FIG. 2 shows a general structure of a field effect transistor as used with respect to various embodiments of the present invention. FIG. 2 shows a body of a semiconductor material 201, which may be part of a bulk semiconductor, silicon-on-insulator (SOI) structure, or any other known crystalline semiconductor surface on which a field effect transistor may be located. Gate conductor 202 is formed on an insulator 202a, which is formed on the semiconductor material 201. Formation of the conductor 201 may be performed by a variety of techniques including lithographic techniques and the like. FIG. 2 next shows deep implant region 203, which may be formed by a dopant deposited or formed on semiconductor material 201 then driven in by one or more techniques possibly including, for example, annealing a higher concentration implant region 204 may be formed as well using similar techniques, although not as deep as implant region 203.

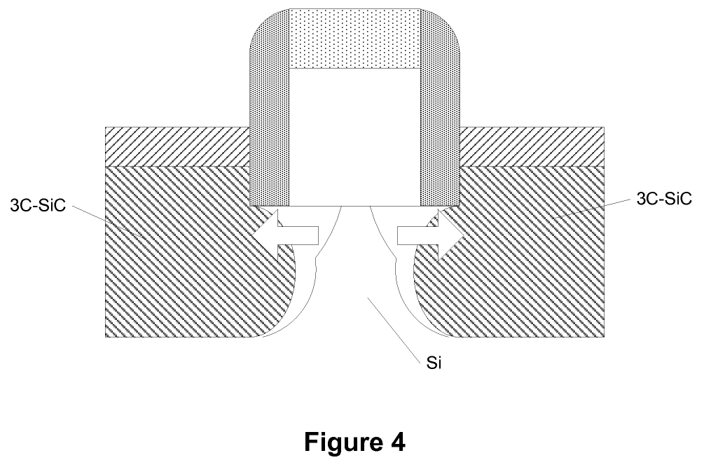

FIG. 2 next shows a gate electrode 205 on top of gate region 202 and sidewalls 206 on either side of gate region 202 and gate electrode 205. Gate electrode 205 may be polysilicon, metal, or metalized lines as are known in the art. FIG. 2 includes source/drain regions 207 and connectors 208. Connectors 208 may be tungsten plugs, polysilicon, metal, or metalized lines as are known in the art. Finally, source/drain extension regions 209 may extend toward a resultant channel region 210. It is appreciated that the structure of FIG. 2 may be modified as known in the art to provide similar field effect transistors. Aspects of the present invention may be applicable to alternate forms of field effect transistors. Further, the order in which various structures of the field effect transistor of FIG. 2 are constructed may be varied as known in the art as well. For the purposes of simplicity and explanation, FIGS. 4-9 are described in relation to a field effect transistor structure similar to that of FIG. 2.

The various embodiments described herein relate to modifying the materials used to in the semiconductor to create stress for channel region 210.

One technique for modifying the stress between one semiconductor region and another semiconductor region is to use materials that have different lattice constants. For example, carbon has a lattice constant that is less than silicon carbide (Si₁₋ₓCₓ), whose lattice constant is less than the lattice constant of silicon, whose lattice constant is less than the lattice constant of silicon germanium (Si₁₋ₓGeₓ), whose lattice constant is less than the lattice constant of germanium. These relationships may be expressed as follows:

a_{carbon}<a_{silicon carbide}<a_{silicon}<a_{silicon germanium}<a_{germanium}

where a is the lattice constant of a material.

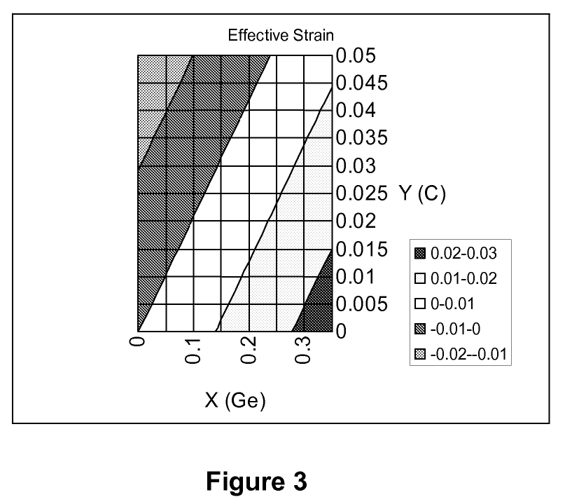

The lattice constant of silicon germanium carbide (Si_{1-x-y}GeₓC_{y}) may vary between the lattice constant of silicon carbide and the lattice constant of silicon germanium depending on the ratio of the silicon to germanium to carbon. FIG. 3 shows linear extrapolations between different lattice constants and the appropriate relative concentrations, using Vegard's law. Vegard's Law states that there is a linear relation between lattice constant and composition of a solid solution at constant temperature.

To determine the values for x and y such that Si_{1-x-y}GeₓC_{y} produces tensile stress as opposed to little or no stress or even compressive stress on an adjacent silicon region, the lattice constant of Si_{1-x-y}GeₓC_{y} for various values of x and y may first be determined. Using linear extrapolations between the various lattice constants for this compound at certain values of x and y as well as Vegard's law for a ternary system, the effective lattice constant for Si_{1-x-y}GeₓC_{y} may be estimated as follows:

a_{SiGeC}=(1-x-y)a_{Si}+x a_{Ge}+y a_{C}

mf_{eff}=[a_{SiGeC}−a_{Si}]/a_{Si}

where a_{Si}=5.43, a_{Ge}=5.82, a_{C}=3.57,

and where a is the lattice constant of a given material and mf_{eff} is the effective mis-fit between the lattice structures of Si_{1-x-y}GeₓC_{y} and crystalline silicon. Using these equations, the effective stress between Si_{1-x-y}GeₓC_{y} and crystalline silicon, versus concentration values for x and y, may be determined. As shown in FIG. 3, negative stress values indicate tensile stress on adjacent silicon and positive stress values indicate compressive stress on adjacent silicon. In addition, the greater the absolute value of the stress value, the greater the amount of resultant stress, either tensile or compressive, on adjacent silicon. FIG. 3 provides a graph showing different concentrations and strain (stress) results.

As a particular non-limiting example, where x is less than 0.1 and y is greater than 0.025, then the resulting Si_{1-x-y}GeₓC_{y} regions (that may include at least part of the source and drain regions) induces a tensile stress on a channel region between the source and drain regions.

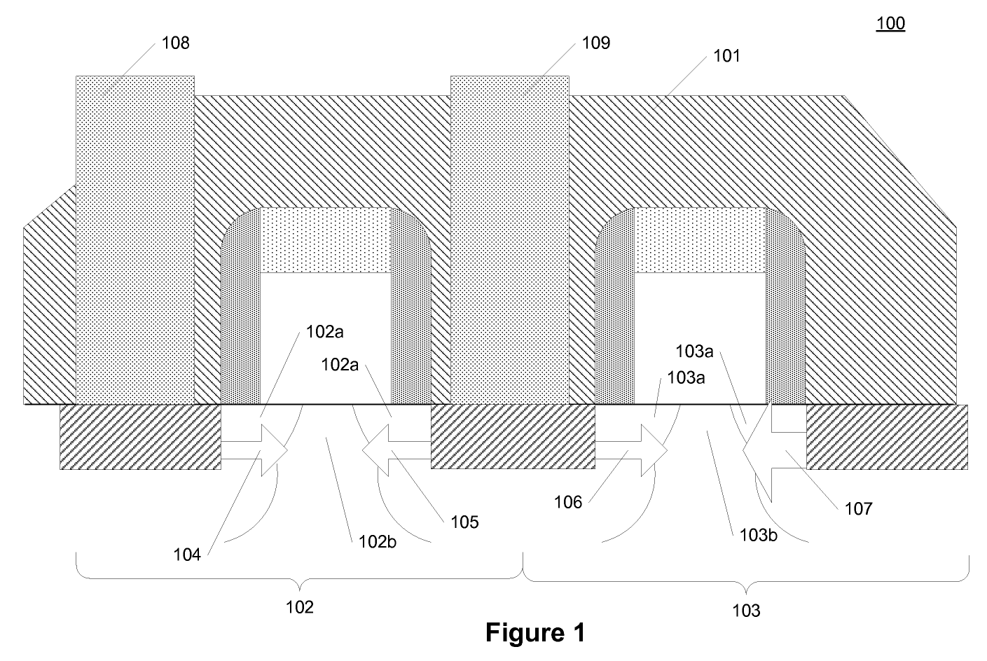

With respect to FIG. 1, stress liners may not be able to provide desired stress levels based on the existence of tungsten plugs or other plugs or modifications to the stress liner. PFETs can benefit from using silicon germanium (Si₁₋ₓGeₓ) as part of the source/drain regions to induce compressive stress for the channel region (for instance, formed of silicon). One or more aspects of the present invention relate to providing combinations of materials that can induce tensile stress for channel regions of NFETs.

Specifically, although it is known to use an embedded SiGe as part of the source/drain regions in a p-type FET to provide tensile stress in the axial direction shown, similar structures are not known for NFETs, especially for generating tensile stress.

In one or more embodiments, various stress-inducing combinations are shown. In particular, in an n-type field effect transistor, these stress inducing structures provide source/drain regions having a lower lattice constant than the channel region. The lattice mismatch that occurs at the junctions between the source/drain regions and the channel region causes the channel region to be under tensile stress. Various selected compositions are shown may generate tensile stress on the channel region. In choosing combinations of materials, their melting points may be taken into account to ensure the practicality of manufacturing these structures.

The following describes various embodiments relating to inducing tensile stress on a channel region through the use of materials having different lattice constants. FIGS. 4-9 are composite Figures in that they generally show the implant regions 203 and 204 as lines under the gate electrodes as represented in FIG. 2 with the differing materials provided on either side of the gate region penetrating into the body of the semiconductor. It is appreciated that the source/drain regions may bridge different materials. Some parts of the source/drain regions may be of the same material as the channel region, some parts of the source/drain regions may be of different materials. In each of FIGS. 4-9, the interface between the various materials may be moved as desired to vary the stress imparted to the channel region.

### First Embodiment

FIG. 4 shows a first embodiment that creates tensile stress for a channel region. Here, silicon is used for the channel region and part of the source/drain regions with 3C—SiC formed outside of the Si channel region.

3C—SiC is known to have a 20% smaller lattice constant (4.36 A) than Si (5.43 A). From this difference in lattice constant, one can infer that an embedded source/drain including this material (3C—SiC) may be effective for generating tensile stress in an n-type FET.

It is noted that the growth temperature for the 3C—SiC material (for instance by epitaxy) is close to the melting point of silicon (which is 1410 C), and so crystal growth of the 3C—SiC may be difficult without compromising the crystalline structure of the silicon. Also, a large lattice mismatch may be formed between the silicon and the 3C—SiC interface thereby causing defects in the crystal interface between the respective regions.

In one or more of the following embodiments, 3C—SiC may be mixed with another semiconductor material with a lower melting point (and, if possible, low lattice constant) to reduce the melting point of the combination sufficiently below that of Si so that known silicon CMOS manufacturing processes can be used.

### Second Embodiment

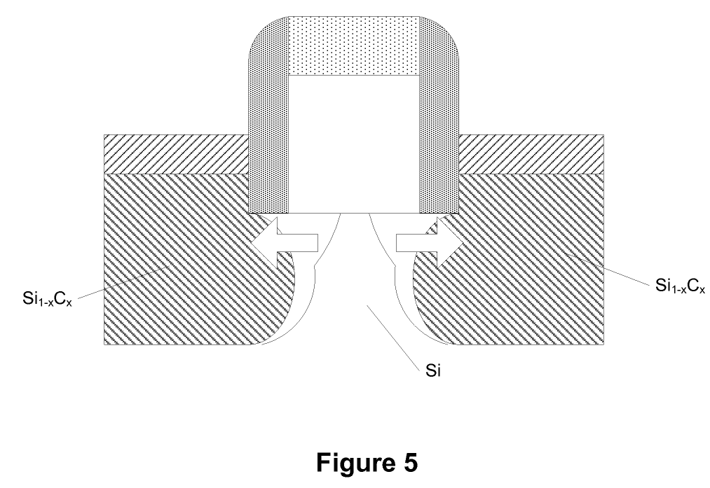

FIG. 5 shows a second embodiment in which silicon is used as the channel region and part of the source/drain regions and silicon carbide is used in the source/drain sides of the field effect transistor. The effective result is tensile stress on the channel region. In some situations, it may be difficult to incorporate carbon into the composition for the source/drain regions. Also, because processing with carbon can require a higher temperature, there may be some silicon crystal degradation.

Here, a silicon carbide alloy Si₁₋ₓCₓ is used as part of the source/drain regions to induce tensile stress in the axial direction shown with a silicon Si channel region. These Si₁₋ₓCₓ layers are known to be metastable. These alloy layers can be achieved by kinetically dominated growth methods (such as molecular beam epitaxy (MBE) or rapid thermal chemical vapor deposition (RTCVD)) at relatively low growth temperatures in comparison with silicon. A significant fraction of carbon atoms, however, are not substantially incorporated, instead forming interstitial defects. Also, a substrate's temperature may rise to the point that the silicon begins to melt and form new defects.

### Third Embodiment

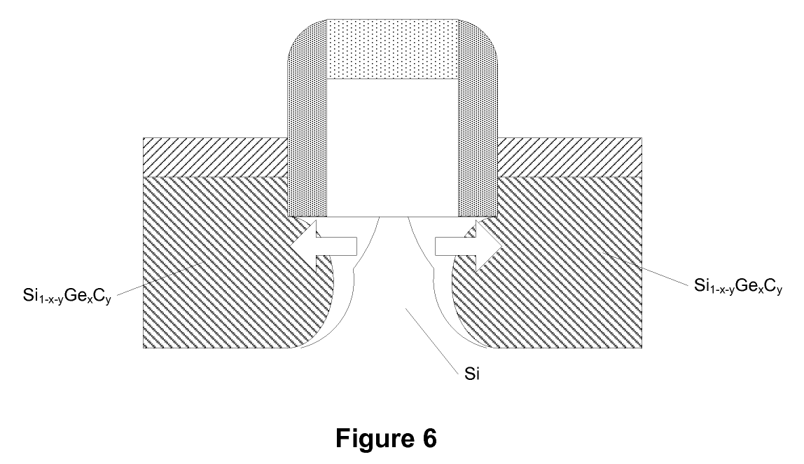

Referring now to FIG. 6, a third embodiment includes a structure for generating tensile stress in the channel region. Here, silicon is used in the channel region with Si_{1-x-y}GeₓC_{y} used in the source/drain areas to impart tensile stress to the channel region. Because of the ability to modify the germanium and carbon concentrations as shown in FIG. 3, the channel region may be subject to tensile stress based certain values of x and y and subject to compressive stress based on other values of x and y. FIG. 6 shows an example where the channel region is under tensile stress (as shown by the arrows pointing away from the channel region).

To manufacture the structure shown in FIG. 6 (as well as other embodiments herein), Si_{1-x-y}GeₓC_{y} epitaxy may be used to form a SiGe:C base layer in a similar manner as conventionally used to form the SiGe:C layer in a standard silicon germanium hybrid bipolar transistor.

### Fourth Embodiment

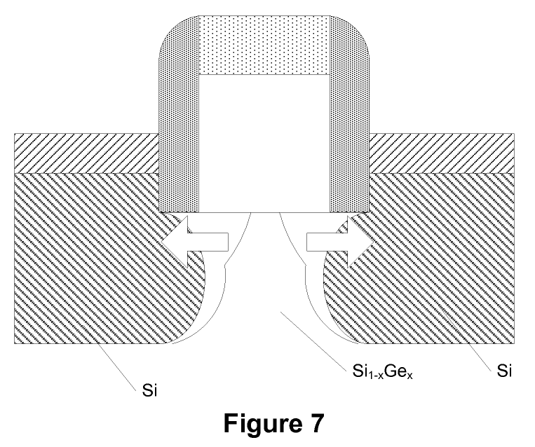

FIG. 7 shows a fourth embodiment of the present invention. Here, silicon germanium Si₁₋ₓGeₓ is used as the crystalline material forming the channel region and silicon used on either side of the field effect transistor. The silicon germanium has a higher lattice constant than the silicon and thus the channel region is placed under tensile stress by the arrangement of the materials.

A special consideration with this embodiment may be the selection of an appropriate gate dielectric material. This is because gate dielectrics containing significant amounts of silicon dioxide may not be compatible with the Si₁₋ₓGeₓ channel region due to poor resulting gate oxide integrity. However, Si₁₋ₓGeₓ can more easily be used with high-K gate dielectrics such as hafnium silicate nitride (HfSiON) or zirconium silicate nitride (ZrSiON). The appropriate value of x in Si₁₋ₓGeₓ to induce tensile stress on adjacent crystalline silicon may be determined using similar linear extrapolation techniques to those discussed above and demonstrated by graph of FIG. 3. In particular, it is desirable to achieve a large lattice constant for the composition Si₁₋ₓGeₓ relative to the silicon regions without being so large that crystalline defects are created along the interface.

### Fifth Embodiment

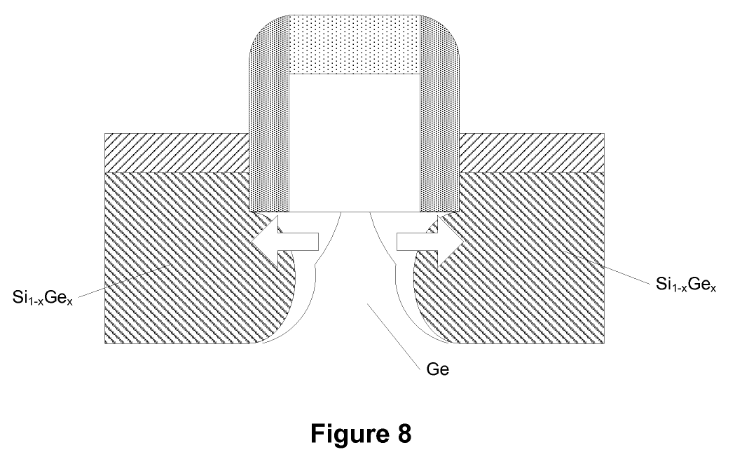

FIG. 8 shows a fifth embodiment of the present invention. Here, germanium is used as the crystalline material forming the channel region and silicon germanium Si₁₋ₓGeₓ is formed on either side of the field effect transistor. The germanium has a larger lattice constant than the silicon germanium and thus the channel region is placed under tensile stress by the arrangement of the materials.

The tensile stress material in FIG. 8 should have a lesser lattice constant than that of the Ge channel region. There is a similar potential issue of the proper selection of a high-k gate dielectric in this embodiment, for example, HfSiON or ZrSiON as with the embodiment of FIG. 7.

### Sixth Embodiment

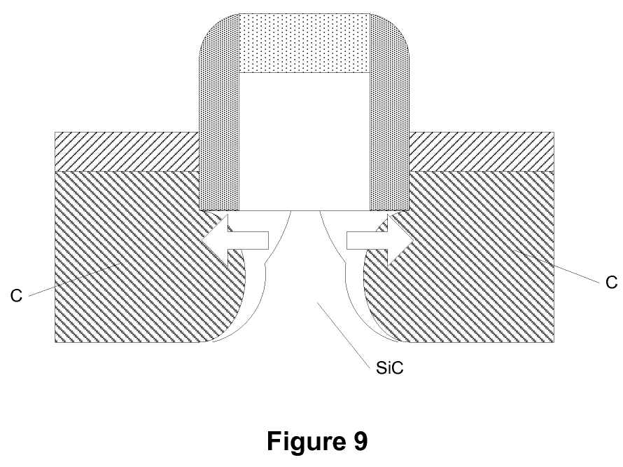

FIG. 9 shows a sixth embodiment of the present invention. Here, silicon carbide is used as the crystalline material forming the channel region and carbon is formed on either side of the field effect transistor. The silicon carbide has a larger lattice constant than the carbon and thus the channel region is placed under tensile stress by the arrangement of the materials.

### Seventh Embodiment

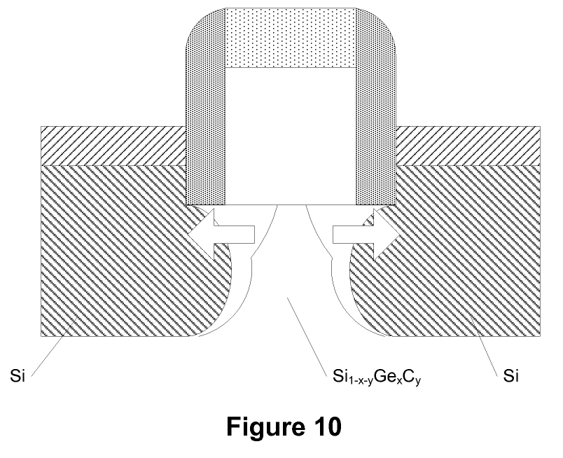

Referring now to FIG. 10, a seventh embodiment includes a structure for generating tensile stress in the channel region. Here, silicon is used in the source/drain areas with Si_{1-x-y}GeₓC_{y} used in the channel region to impart tensile stress to the channel region. Because of the ability to modify the germanium and carbon concentrations as shown in FIG. 3, the channel region may be subject to tensile stress based certain values of x and y and subject to compressive stress based on other values of x and y. FIG. 10 shows an example where the channel region is under tensile stress (as shown by the arrows pointing away from the channel region). In comparison, the amount of germanium in the Si_{1-x-y}GeₓC_{y} material of the seventh embodiment is larger than the amount of germanium in the Si_{1-x-y}GeₓC_{y} material of the third embodiment. Similarly, the amount of carbon in the Si_{1-x-y}GeₓC_{y} material of the seventh embodiment is smaller than the amount of carbon in the Si_{1-x-y}GeₓC_{y} material of the third embodiment.

In at least FIGS. 4-10, structures may be constructed, for example, using kinetically dominated growth methods at relatively low temperatures such as molecular beam epitaxy and rapid thermal chemical vapor deposition. From a review of the various disclosed illustrative embodiments, other possible structures may come to mind which should be considered within the scope of the invention which should only be considered limited by the scope of the claims which follow. For example, other semiconductor materials may come to mind as a source/drain tensile stress generator so long as their effective lattice constant is relatively less than that of the material used for the channel region and so long as the melting points of the materials or compositions of materials are less than that of Si so that conventional Si CMOS manufacturing techniques may be employed.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims. Numerous other embodiments, modifications and variations within the scope and spirit of the appended claims will occur to persons of ordinary skill in the art from a review of this disclosure.

What is claimed is:

1. A semiconductor device, comprising:
a semiconductor layer;
a field-effect transistor formed on a first material, the field-effect transistor having:
a gate insulator on the first material,
a conductive gate disposed on the gate insulator,
a channel region of a first material disposed in the first material underneath the first material, the first material having a first lattice constant,
a source region, and
a drain region, the source and drain regions being at least partially formed of a second material having a lower effective lattice constant than the first material and disposed in the semiconductor layer on opposing sides of the channel region,
wherein the second material induces a tensile stress on the channel region.

2. The semiconductor device as recited in claim 1, where silicon Si is the first material.

3. The semiconductor device as recited in claim 1, where silicon Si is the second material.

4. The semiconductor device as recited in claim 1, where silicon germanium carbide Si_{1-x-y}GeₓC_{y} is the first material.

5. The semiconductor device as recited in claim 1, where silicon germanium carbide Si_{1-x-y}GeₓC_{y} is the second material.

6. The semiconductor device as recited in claim 1, where 3C—SiC is the first material.

7. The semiconductor device as recited in claim 1, where silicon germanium Si₁₋ₓGeₓ is the first material.

8. The semiconductor device as recited in claim 1, where silicon germanium Si₁₋ₓGeₓ is the second material.

9. The semiconductor device as recited in claim 1, where germanium Ge is the first material.

10. The semiconductor device as recited in claim 1, where silicon carbide SiC is the first material.

11. The semiconductor device as recited in claim 1, where silicon carbide SiC is the second material.

12. The semiconductor device as recited in claim 1, where carbon C is the second material.

13. The semiconductor device as recited in claim 4,
wherein the lattice constant of Si_{1-x-y}GeₓC_{y} is determined according to a_{SiGeC}=(1-x-y) a_{Si}+x a_{Ge}+y a_{C} and mf_{eff}=[a_{SiGeC}−a_{Si}]/a_{Si} and the lattice constants for silicon, germanium and carbon being known.

14. The semiconductor device as recited in claim 5,
wherein the lattice constant of Si_{1-x-y}GeₓC_{y} is determined according to a_{SiGeC}=(1-x-y) a_{Si}+x a_{Ge}+y a_{C} and mf_{eff}=[a_{SiGec-a}_{Si}]/a_{Si} and the lattice constants for silicon, germanium and carbon being known.

15. A semiconductor device, comprising:
a field-effect transistor having a channel region and source and drain regions,
wherein the source and drain regions include a first material composition having a lower effective lattice constant than that of a second material composition of the channel region, the first material composition being arranged so as to induce a tensile stress on the channel region.

16. The semiconductor device as recited in claim 6 where silicon is utilized as the channel region.
